(19) United States
(12) Patent Application Publication
(10) Pub. No.: US 2014/0231492 A1
(43) Pub. Date: Aug. 21, 2014

(54) ELECTRONIC COMPONENT MOUNTING METHOD, ELECTRONIC COMPONENT PLACEMENT MACHINE, AND ELECTRONIC COMPONENT MOUNTING SYSTEM

(71) Applicants: Tsubasa Saeki, Osaka (JP); Yoshiyuki Wada, Osaka (JP); Koji Motomura, Osaka (JP); Tadahiko Sakai, Osaka (JP)

(72) Inventors: Tsubasa Saeki, Osaka (JP); Yoshiyuki Wada, Osaka (JP); Koji Motomura, Osaka (JP); Tadahiko Sakai, Osaka (JP)

(73) Assignee: PANASONIC CORPORATION, Osaka (JP)

(21) Appl. No.: 14/117,624

(22) PCT Filed: May 23, 2012
(86) PCT No.: PCT/JP2012/003356

§ 371 Date: Nov. 13, 2013

(30) Foreign Application Priority Data
May 26, 2011 (JP) 2011-118000

(51) Int. Cl. H05K 13/04

(52) U.S. Cl. CPC H05K 13/0465
USPC 228/180.22; 228/7

(57) ABSTRACT

Disclosed is an electronic component mounting method including the steps of: providing a first electronic component having a principal surface provided with a plurality of bumps; providing a substrate having a plurality of first electrodes corresponding to the plurality of bumps; applying flux to the plurality of bumps; placing the first electronic component on the substrate such that the bumps land on the corresponding first electrodes via the flux; dispensing a thermosetting resin to at least one reinforcement position on the substrate with the first electronic component placed thereon, the at least one reinforcement position corresponding to a peripheral edge portion of the first electronic component; and heating the substrate with the first electronic component placed thereon, to melt the bumps and cure the thermosetting resin, followed by cooling, thereby to join the first electronic component to the substrate.

### TECHNICAL FIELD

The present invention relates to a method and a machine for placing or mounting, on a substrate, an electronic component having a plurality of bumps.

### BACKGROUND ART

Various electronic components are incorporated in electronic devices. These electronic components are joined at predetermined positions on a substrate having a plurality of electrodes and lead frames, and are incorporated as such as a mounting structure in the devices. With the advancement of miniaturization of electronic devices in recent years, the electronic components incorporated in the devices are being more and more miniaturized, thus causing increased use of small-sized electronic components such as flip chips and chip size packages (CSPs) to be place on a substrate.

Electronic components such as flip chips and CSPs have a principal surface on which a plurality of terminals are regularly arranged in an array, and each terminal has a solder bump formed thereon. In mounting such an electronic component on the substrate, the bumps are allowed to land on the electrodes on the substrate, called lands. Thereafter, the bumps are heated and melted (ref lowed), and then left to cool, so that the interconnection between the electronic component and the substrate is achieved. As a result, the terminals of the electronic component are electrically connected with the electrodes of the substrate, whereas the electronic component is held on the substrate via solder joints.

In addition to electronic components such as flip chips and CSPs, electronic components called chip resistors, chip LEDs, and chip capacitors are often mounted in mounting structures. Such electronic components are placed on electrodes on a substrate, after a paste containing metal particles (e.g., cream solder) is applied to the electrodes by a method such as screen printing. Thereafter, the metal particles are melted by reflowing and left to cool, whereby the electronic components are joined to the substrate. In general, the paste containing metal particles is applied to the electrodes on a substrate before electronic components such as flip chips and CSPs are placed on the substrate.

When thermal stress generated by thermal cycling, or external force, is applied to a mounting structure comprising a substrate and electronic components obtained through the aforementioned mounting process, and if the electronic components are joined to the substrate via the bumps, the solder joints may lack sufficient strength. As a countermeasure, a reinforcing resin is used to join the electronic components to the substrate, thereby to reinforce the solder joints.

One method of reinforcing the solder joints with a reinforcing resin is to allow an underfill material to enter gaps between the substrate and the principal surface of the electronic component having bumps thereon. However, the underfill material should be injected into the gaps between the electronic component and the substrate, after interconnection between the electronic component and the substrate has been established by ref lowing. Therefore, an additional heating for thermally curing the underfill material is required, which increases the number of processes required for mounting. Moreover, the area where the underfill material adheres is large, and this is inconvenient when repairing the mounting structure. Furthermore, when the substrate having solder joints reinforced with an underfill material is reflowed again, solder bridging is likely to occur at gaps caused in the underfill material.

Therefore, a proposal has been made for a method of dispensing a reinforcing resin onto a substrate in advance before placing thereon an electronic component, only at positions which correspond to those on the peripheral edge portion of the electronic component (c.f., Patent Literature 1). According to this method, during ref lowing, the reinforcing resin can be cured while soldering is being performed. Furthermore, this method is better in terms of facilitating repair work on the mounting structure, and also in terms of reduced occurrence of solder bridging when reflow is performed again.

### CITATION LIST

### Patent Literature

[PTL 1] Japanese Laid-Open Patent Publication No. 2003-218508

### SUMMARY OF INVENTION

### Technical Problem

On the substrate on which an electronic component is to be placed, terminals are regularly arranged in an array so as to correspond to the bumps on the electronic component. In Patent Literature 1, prior to the placement of the electronic component on the substrate, a reinforcing resin is dispensed onto a plurality of reinforcement positions outside the electrodes at the outermost periphery. Thereafter, the electronic component is placed on the substrate such that the bumps with flux applied thereto land on the electrodes. At that time, by bringing the reinforcing resin into contact with the peripheral edge portion of the electronic component, the reinforcing resin acts as an adhesive for fixing the electronic component to the substrate until the process proceeds to the reflow process. After reflowing, the reinforcing resin becomes a reinforcing portion for reinforcing the solder joints.

In the case of dispensing a reinforcing resin onto the substrate prior to the placement of an electronic component on the substrate as mentioned above, the reinforcing resin may touch or contact with the electrodes provided on the substrate. If such contact occurs, the reinforcing resin enters between the bumps and the electrodes. When reflowing is performed in this state, the reinforcing resin becomes an obstacle, preventing the flux from coming in sufficient contact with the electrodes. As a result, the molten bumps may fail to spread and wet the electrodes, leading to poor junction (poor electrical connection and insufficient joining strength). With the advancement of miniaturization of electronic components in recent years, it is becoming more and more difficult to avoid contact between the above-described reinforcing resin and the electrodes provided on the substrate.

### Solution to Problem

In view of the above, the present invention intends to provide an electronic component mounting method, electronic component placement machine, and electronic component mounting system that enable to prevent poor junction between the electronic component and the substrate, with a smaller number of processes.

One aspect of the present invention relates to an electronic component mounting method including the steps of:

providing a first electronic component having a principal surface provided with a plurality of bumps;

providing a substrate having a plurality of first electrodes corresponding to the plurality of bumps;

applying flux to the plurality of bumps;

placing the first electronic component on the substrate such that the bumps land on the corresponding first electrodes via the flux;

dispensing a thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion; and

heating the substrate with the first electronic component placed thereon to melt the bumps and cure the thermosetting resin, followed by cooling, thereby to join the first electronic component to the substrate.

Another aspect of the present invention relates to an electronic component placement machine adapted to place a first electronic component on a substrate, the first electronic component having a principal surface provided with a plurality of bumps, the substrate having a plurality of first electrodes corresponding to the plurality of bumps.

The machine includes:

a first component feeding unit for feeding the first electronic component;

a substrate holder for holding and positioning the substrate;

a transfer unit for providing a film of flux;

a movable placing head for placing the fed first electronic component on the substrate;

a movable dispensing head for dispensing a thermosetting resin; and

a control unit for controlling movements and operations of the placing head and the dispensing head.

In response to commands from the control unit, the placing head transfers the film of the flux to the plurality of bumps on the first electronic component, using the transfer unit, and then places the first electronic component on the substrate such that the bumps land on the corresponding first electrodes via the flux; and the dispensing head dispenses the thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion.

Yet another aspect of the present invention relates to an electronic component mounting method in which a first electronic component and a second electronic component are mounted on a substrate, the first electronic component having a principal surface provided with a plurality of bumps, the second electronic component having a connection terminal, the substrate having a plurality of first electrodes corresponding to the plurality of bumps and a second electrode corresponding to the connection terminal.

The method includes the steps of:

providing the substrate;

applying a paste containing metal particles by screen printing to the second electrode on the substrate;

providing the first electronic component;

providing the second electronic component;

applying flux to the plurality of bumps;

placing the first electronic component on the substrate such that the bumps land on the corresponding first electrodes via the flux;

dispensing a thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion;

placing the second electronic component on the substrate such that the connection terminal lands on the second electrode via the paste containing metal particles; and

heating the substrate with the first electronic component and the second electronic component placed thereon, to melt the bumps and the metal particles, and cure the thermosetting resin, followed by cooling, thereby to join the first electronic component and the second electronic component to the substrate.

Still another aspect of the present invention relates to an electronic component mounting system adapted to mount a first electronic component and a second electronic component on a substrate, the first electronic component having a principal surface provided with a plurality of bumps, the second electronic component having a connection terminal, the substrate having a plurality of first electrodes corresponding to the plurality of bumps and a second electrode corresponding to the connection terminal.

The system includes:

a substrate feeding machine for feeding the substrate;

a screen printing machine for applying a paste containing metal particles by screen printing to the second electrode on the substrate carried from the substrate feeding machine;

an electronic component placement machine for placing the first electronic component and the second electronic component on the first electrodes and the second electrode, respectively, on the substrate carried from the screen printing machine, the second electrode having the paste containing metal particles applied thereto; and

a reflow machine for heating the substrate carried from the electronic component placement machine, to melt the bumps and the solder, and cure the thermosetting resin.

The electronic component placement machine includes:

a first component feeding unit for feeding the first electronic component;

a second component feeding unit for feeding the second electronic component;

a substrate holder for holding and positioning the substrate;

a transfer unit for providing a film of flux;

a movable placing head for placing the fed first electronic component and the fed second electronic component on the substrate;

a movable dispensing head for dispensing the thermosetting resin; and

a control unit for controlling movements and operations of the placing head and the dispensing head.

In response to commands from the control unit, the placing head transfers the film of the flux to the plurality of bumps on the first electronic component, using the transfer unit, and then places the first electronic component on the substrate such that the bumps land on the corresponding first electrodes via the flux and places the second electronic component on the substrate such that the connection terminal lands on the second electrode via the paste containing metal particles; and the dispensing head dispenses the thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion.

### ADVANTAGEOUS EFFECTS OF INVENTION

According to the present invention, an electronic component is placed on a substrate, and then a thermosetting resin is dispensed at a reinforcement position corresponding to the peripheral edge portion of the electronic component. Therefore, even when the thermosetting resin touches or contacts with the electrodes provided on the substrate or the bumps, the thermosetting resin is unlikely to enter between the electrodes and the bumps. Hence, the electrodes are sufficiently wetted with the molten bumps during reflowing, and therefore, electrical connection and sufficient joining strength at the solder joints can be ensured.

While the novel features of the invention are set forth particularly in the appended claims, the invention, both as to organization and content, will be better understood and appreciated, along with other objects and features thereof, from the following detailed description taken in conjunction with the drawings.

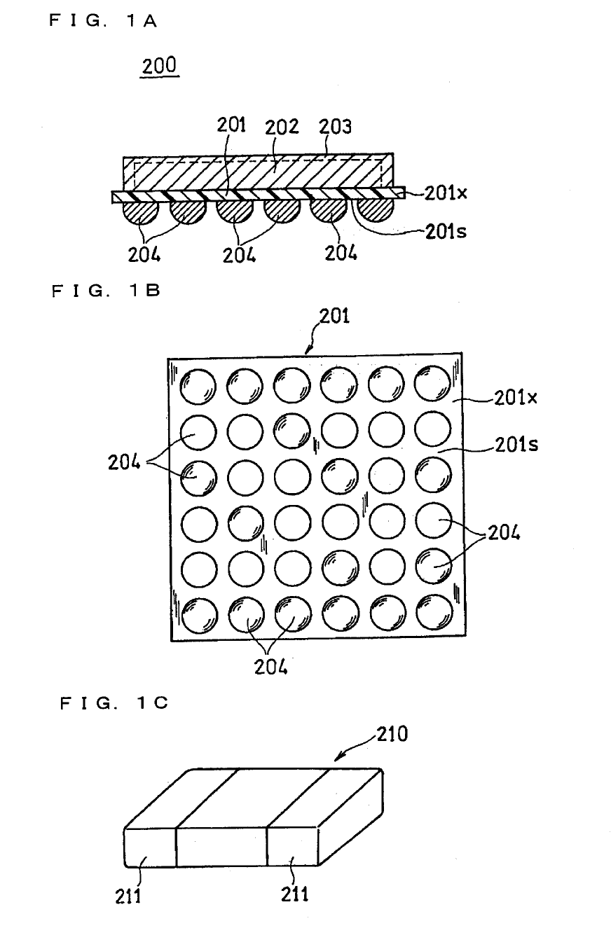

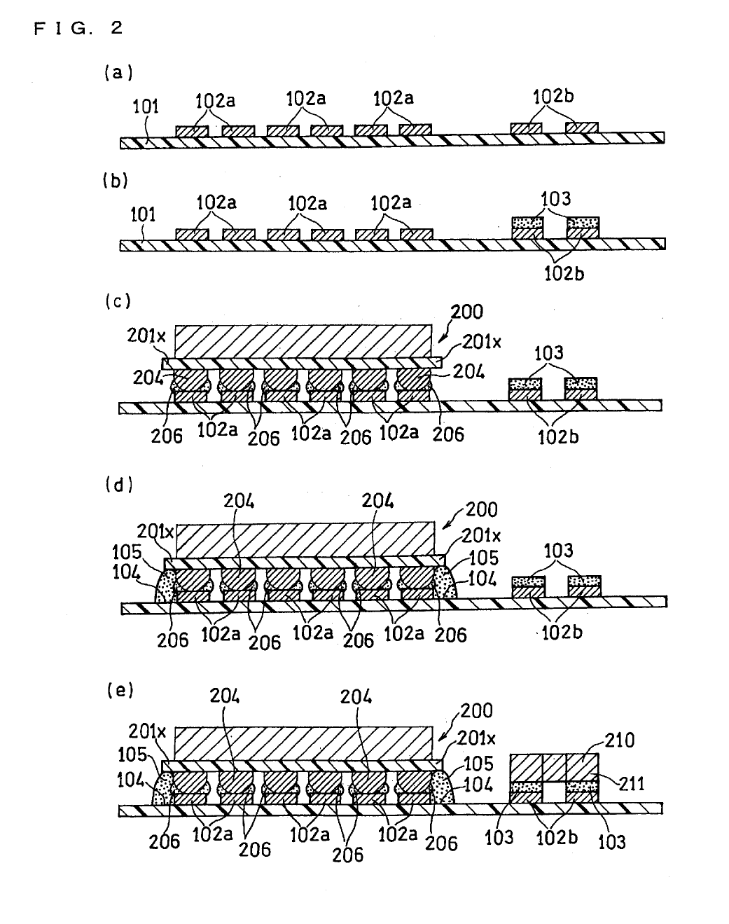

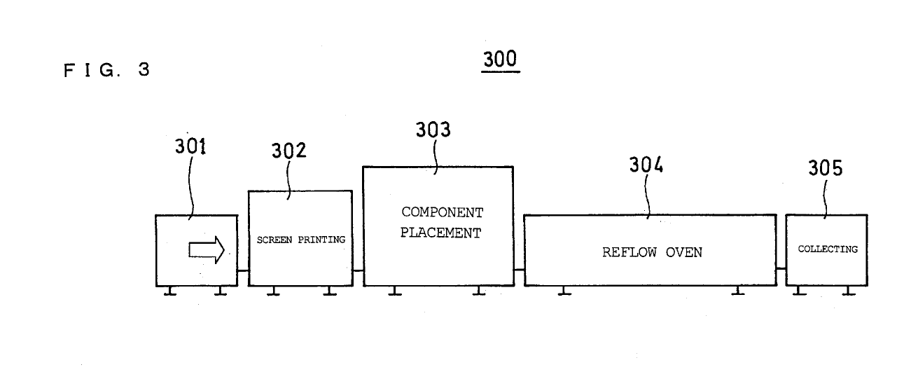

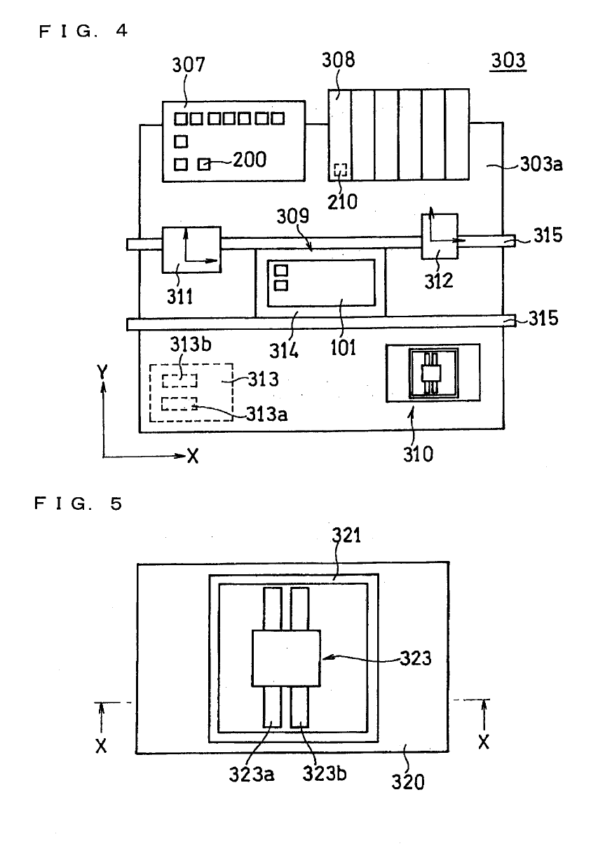

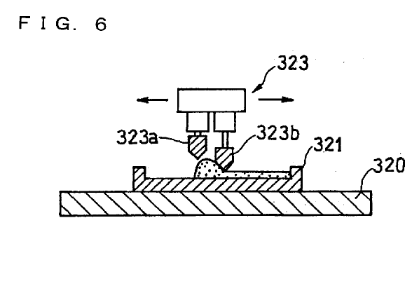

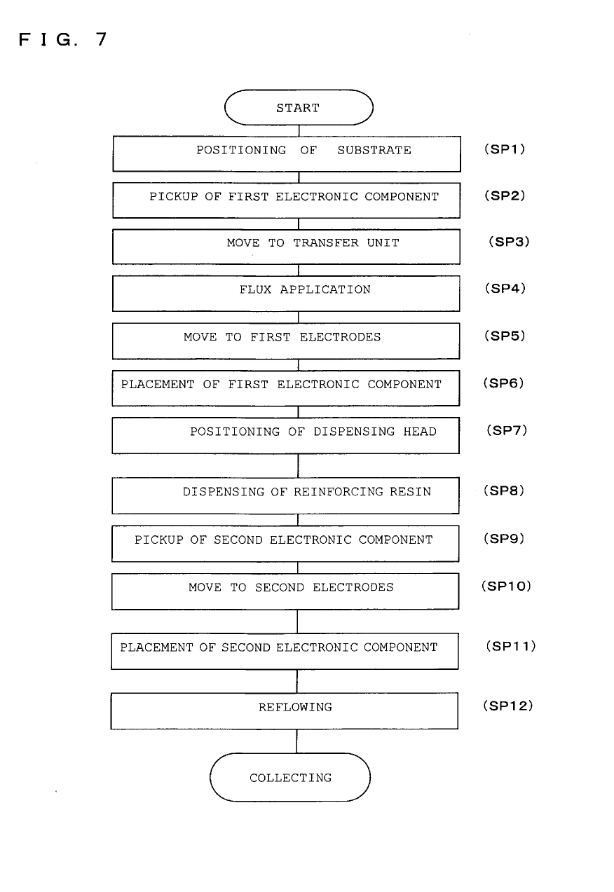

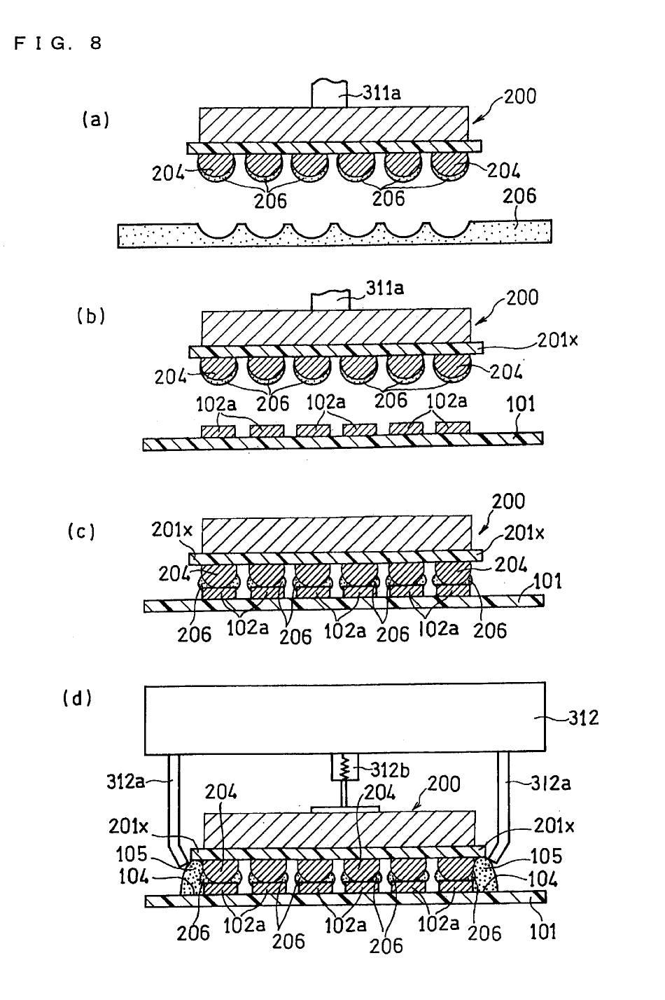

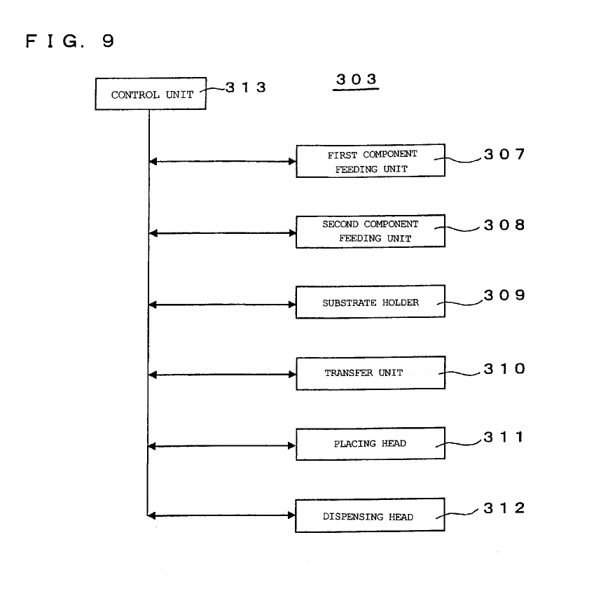

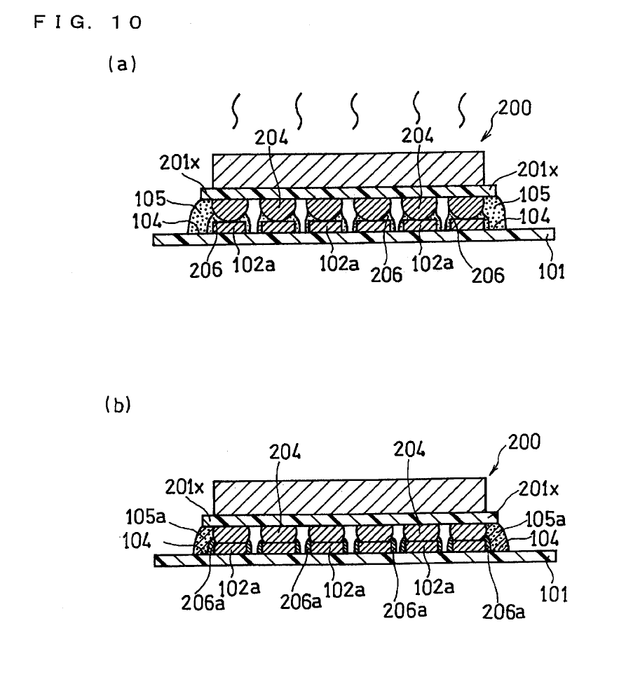

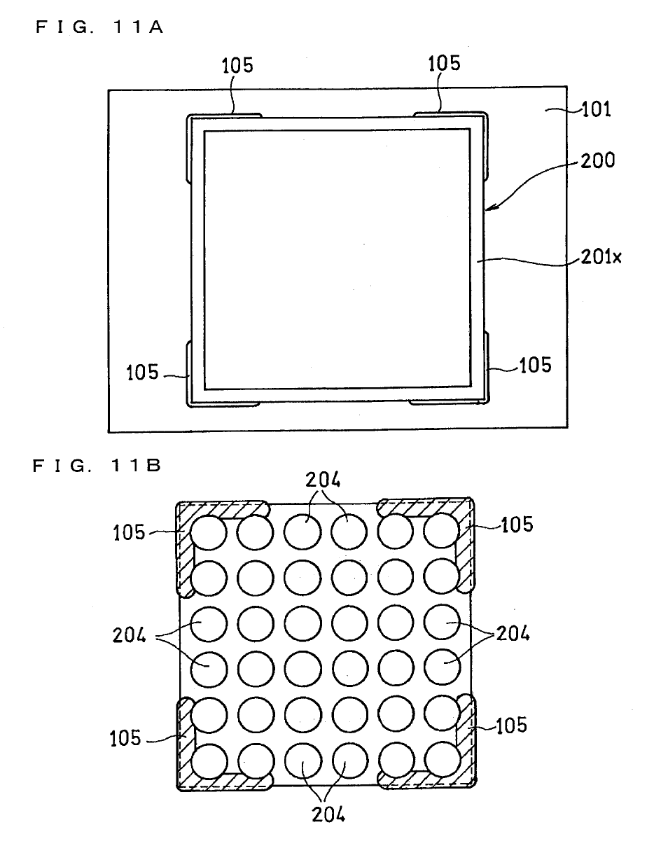

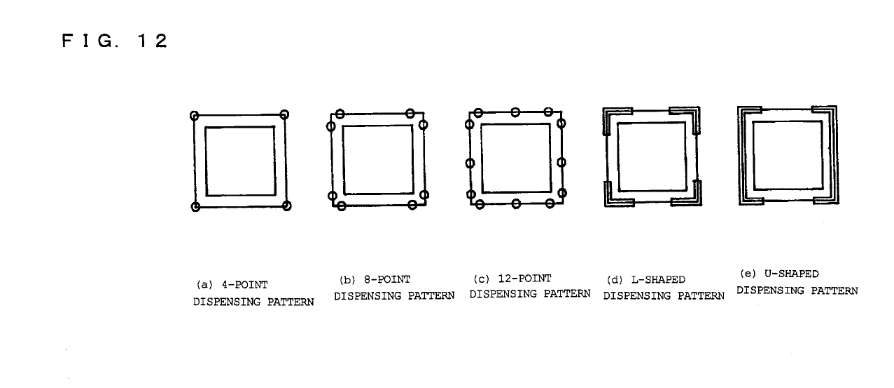

### BRIEF DESCRIPTION OF DRAWINGS

[FIG. 1A] A front view of an example of a first electronic component having a plurality of bumps

[FIG. 1B] A bottom view of the electronic component of FIG. 1A

[FIG. 1C] An oblique view of an example of a chip-type second electronic component

[FIG. 2] A series of drawings to explain a process of an electronic component mounting method according to one embodiment of the present invention, in which a first electronic component and a second electronic component are placed on a substrate

[FIG. 3] A diagram showing the overall flow of an electronic component mounting system according to one embodiment of the present invention

[FIG. 4] A configuration drawing of an electronic component placement machine according to one embodiment of the present invention, seen from above

[FIG. 5] A top view of a transfer unit

[FIG. 6] A view taken along the line X-X of the transfer unit

[FIG. 7] A flowchart of the steps for placing a first electronic component and a second electronic component on a substrate

[FIG. 8] A series of drawings to explain a process of placing a first electronic component on a substrate

[FIG. 9] A diagram showing a control system in an electronic component placement machine according to one embodiment of the present invention

[FIG. 10] A set of schematic drawings illustrating the solder joints when the substrate with the first component placed thereon is heated in a reflow process

[FIG. 11A] A plan view of a rectangular first electronic component with a reinforcing resin dispensed at four reinforcement positions

[FIG. 11B] A bottom view of the electronic component of FIG. 11A

[FIG. 12] A set of exemplary dispensing patterns of reinforcing resin

### DESCRIPTION OF EMBODIMENTS

First, the structure of an electronic component to be placed on a substrate is described.

FIG. 1A is a front view of an example of a first electronic component 200, and FIG. 1B is a bottom view thereof. The first electronic component 200 is a ball grid array (BGA) electronic component, which is to be connected to the electrodes (lands) on a substrate 101 via a plurality of bumps 204. The first electronic component 200 includes a thin substrate (inner substrate) 201, a semiconductor element 202 mounted on the upper surface thereof, and a resin sealant 203 encapsulating the semiconductor element 202. The lower surface of the inner substrate 201 is a principal surface 201s of the first electronic component. The principal surface 201s has thereon a plurality of terminals regularly arranged in an array, and the bump 204 is formed on each of the terminals.

The structure of the first electronic component is not limited to that illustrated in FIGS. 1A and 1B. Examples of the first electronic component include various forms of flip chips and chip size packages (CSPs).

FIG. 1C is an oblique view of an example of a second electronic component 210, which is optionally mounted on the substrate 101 together with the first electronic component 200. The second electronic component is a chip component having at least one connection terminal 211, and is, for example, a chip resistor, chip LED, or chip capacitor.

Next, an electronic component mounting method of the present invention is described.

The electronic component mounting method according to the present invention includes the steps of: providing the first electronic component 200 having a principal surface provided with the plurality of bumps 204; providing the substrate 101 having a plurality of first electrodes corresponding to the plurality of bumps 204; applying flux to the plurality of bumps 204; placing the first electronic component 200 on the substrate 101 such that the bumps 204 land on the corresponding first electrodes via the flux; dispensing a thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion; and heating the substrate 101 with the first electronic component 200 placed thereon, to melt the bumps 204 and cure the thermosetting resin, followed by cooling, thereby to join the first electronic component 200 to the substrate 101.

The electronic component mounting method of the present invention may further include the steps of: providing the second electronic component 210 having the connection terminal 211; before placing the first electronic component 200 on the substrate 101, applying a paste containing metal particles by screen printing to a second electrode which is provided on the substrate 101 and corresponds to the connection terminal 211; and placing the second electronic component 210 on the substrate 101 such that the connection terminal 211 lands on the second electrode via the paste containing metal particles.

In the following, an exemplary method in which the first and second electronic components 200 and 210 are placed on the substrate 101 is described.

The substrate 101 is, as illustrated in FIG. 2(a), provided with first electrodes 102a to be connected to the bumps 204 on the first electronic component 200, and second electrodes 102b to be connected with the terminals 211 of the second electronic component 210.

First, as illustrated in FIG. 2(b), a paste 103 containing metal particles (e.g., solder particles) is applied to the second electrode 102b by a method such as screen printing, with the first electrodes 102a covered with a mask or handled otherwise.

Next, flux 206 is applied to the bumps 204 of the first electronic component 200, and then, as illustrated in FIG. 2(c), the first electronic component 200 is placed on the substrate. At that time, all of the bumps 204 land on the corresponding first electrodes 102a, via the flux 206. Consequently, not only the bumps 204, but also all of the first electrodes 102a become sufficiently wet with the flux 206. The method of applying the flux 206 to the bumps 204 is preferably, but not limited to, a method of transferring the flux 206 to the bumps 204 from a film of the flux 206 formed on a flat plane, by using a squeegee.

Thereafter, as illustrated in FIG. 2(d), a thermosetting resin is dispensed as a reinforcing resin 105 onto at least one reinforcement position 104 on the substrate 101 with the first electronic component 200 placed thereon, the at least one reinforcement position corresponding to a peripheral edge portion 201x of the first electronic component 200, the thermosetting resin dispensed so as to come in contact with the peripheral edge portion 201x. At that time, since the bumps 204 are already placed on the first electrodes 102a, the reinforcing resin 105 will be prevented from entering between the first electrodes 102a and the bumps 204. Therefore, the first electrodes 102a and the bumps 204 are kept bridged to each other via the flux 206. Note that the reinforcement positions 104 preferably correspond, not to the entire peripheral edge portion 201x, but, for example, to the four corners, or vicinities thereof, of the first electronic component 200 of which the principal surface 201s is rectangular.

Thereafter, as illustrated in FIG. 2(e), the second electronic component 210 is placed on the substrate 101. Here, the second electronic component 210 may be placed either before or after the first electronic component 200 is placed.

The substrate 101 with the first and second electronic components 200 and 210 placed thereon is heated in a reflow machine. Here, as described above, since the entry of the thermosetting resin 105 between the bumps 204 and the first electrodes 102a is prevented by allowing the bumps 204 to land on the first electrodes 102a in advance before the thermosetting resin 105 is dispensed, the bumps 204 are reflowed, while the first electrodes 102a are bridged to the bumps 204 via the flux 206. Therefore, the molten bumps sufficiently spread and wet the first electrodes 102a, and electrical connection and sufficient joining strength are ensured at solder joints. The metal particles in the paste 103 also melt by reflowing, and spread and wet the second electrodes 102b. After the reflow process, the solder is cooled and solidified, and the terminals of the first and second electronic components 200 and 210 are joined to their corresponding electrodes on the substrate 101.

In order for the self-alignment effect to not be obstructed by the reinforcing resin 105 in the reflow process, the reinforcing resin 105 is preferably formulated such that the resin is thermally cured after the first electrodes 102a have been sufficiently wetted with the molten bumps. The viscosity of the reinforcing resin 105 before thermal curing tends to decrease with increase in temperature. Therefore, by allowing the curing reaction of the reinforcing resin to finish after the melting of the bumps, the molten bumps can easily exert their self-alignment effect. For example, by setting the curing temperature of the reinforcing resin 105 to be higher than the melting temperature (melting point) of the bumps 204, the self-alignment effect can be exerted reliably.

FIG. 3 shows the overall flow of an exemplary electronic component mounting system (electronic component mounting line) for carrying out the electronic component mounting method of the present invention.

An electronic component mounting system 300 includes: a substrate feeding machine 301 for feeding a substrate on which electronic components are to be mounted; a screen printing machine 302 for applying a paste containing metal particles by screen printing to pre-selected electrodes (second electrodes 102b) on the substrate carried from the substrate feeding machine 301; an electronic component placement machine 303 for placing a first electronic component on electrodes (first electrodes 102a) on the substrate carried from the screen printing machine 302, the first electrodes being different from the aforementioned pre-selected second electrodes, and placing a second electronic component on the electrodes with the metal particle-containing paste applied thereto; and a reflow machine 304 for heating the substrate carried from the electronic component placement machine 303, thereby to join the first and second electronic components to the substrate. The substrate carried from the reflow machine 304, i.e., a mounting structure, is collected by a substrate collecting machine 305.

FIG. 4 is a configuration drawing of the electronic component placement machine 303, seen from above, included in the electronic component mounting system 300. The electronic component placement machine 303 includes: a first component feeding unit 307 for feeding the first electronic component 200; a second component feeding unit 308 for feeding the second electronic component 210; a substrate holder 309 for holding and positioning the substrate 101; a transfer unit 310 for providing a film of flux; and a base 303a on which they are disposed.

The electronic component placement machine 303 further includes: a movable placing head 311 for placing the fed first and second electronic components 200 and 210 on the substrate 101; a movable dispensing head 312 for dispensing a thermosetting resin as a reinforcing resin 105; and a control unit 313 for controlling the movements and operations of the placing head 311 and the dispensing head 312. The placing head 311 and the dispensing head 312 are supported by an X-Y movement mechanism (not shown) exclusive to each head. The X-Y movement mechanism is controlled by the control unit 313, and enables movements of each of the heads in the space above the base 303a.

The first component feeding unit 307 may have any structure, and includes, but not particularly limited to, a tray feeder for feeding a tray having thereon the first electronic components 200 arranged in a grid, to the pickup position of the placing head 311.

The first electronic component 200 is a comparatively small-sized BGA electronic component, as illustrated in FIGS. 1A and 1B, having a principal surface 201s provided with bumps 204.

The second component feeding unit 308 may also have any structure, and includes, but not particularly limited to, a tape feeder for feeding a tape at a predetermined pitch to the pickup position of the placing head 311, the tape holding the second electronic components 210 with a predetermined distance therebetween. The second electronic component 210 is not particularly limited, and is, for example, an electronic component other than those of BGA type, such as one having connection terminals as illustrated in FIG. 1C.

The substrate holder 309 for holding and positioning the substrate 101 may have any structure, and comprises, for example, as illustrated in FIG. 4, substrate carrying conveyors 315 for carrying a carrier 314 holding the substrates 101. The substrate carrying conveyors 315 carry the substrate 101 to where the placement of each of the electronic components is performed, and positions it there. The substrate carrying conveyors 315 therefore function as the substrate holder 309.

The placing head 311 includes a suction nozzle that is moved up and down by a built-in up-and-down movement mechanism. The placing head 311 picks up the first electronic component 200 from the first component feeding unit 307, and the second electronic component 210 from the second component feeding unit 308, by the suction nozzle moving down and up and performing suction. Each of the electronic components is placed on the substrate 101, by the suction nozzle moving down and up and performing suction release (vacuum break) from above the predetermined point of the substrate 101.

The movable dispensing head 312 for dispensing the thermosetting resin as the reinforcing resin 105 has therein a dispenser having a dispensing nozzle that ejects the reinforcing resin 105, and an up-and-down movement mechanism that moves the dispensing nozzle up and down. In this embodiment, the dispensing head 312 is supported by an exclusive X-Y movement mechanism and allowed to move in a predetermined space including the space above the base 303a. The dispensing head 312 may be integrated together with the placing head 311, and they may move as one in the space above the base table 303a by a shared X-Y movement mechanism.

The movements of the placing head 311 and the operations thereof such as picking up and placing of the electronic components are controlled by commands from the control unit 313. Likewise, the movements of the dispensing head 312 and the operations thereof such as ejecting of the reinforcing resin 105 therefrom are controlled by commands from the control unit 313. The control unit 313 comprises, for example: a memory 313a that stores programs for controlling the movements and operations of the placing head 311 and the dispensing head 312; a central arithmetic unit 313b, such as CPU or MPU; various interfaces; and/or a personal computer.

The transfer unit 310 for providing the film of the flux is not particularly limited, and may be any one that has a mechanism capable of providing the film of the flux having a thickness suitable for being transferred to the bumps 204 on the first electronic component 200. For example, as illustrated in FIG. 5, the transfer unit 310 comprises: a base table 320; a transfer table 321 disposed on top of the base table 320; and a squeegee unit 323 disposed above the transfer table 321. The squeegee unit 323 comprises a first squeegee member 323a and a second squeegee member 323b, both having a length nearly equal to the width of the transfer table in the Y-axis direction thereof; and they are arranged in parallel to the Y-axis direction with a certain distance therebetween. The squeegee members are freely movable up and down, i.e., freely movable toward and away from the film formed on the transfer table 321, by an up-and-down movement mechanism built in the squeegee unit 323.

As illustrated in FIG. 6, after the flux 206 has been provided between the first squeegee member 323a and the second squeegee member 323b, the squeegee unit 323 is moved in directions indicated by the arrows, and the first and second squeegee members 323a and 323b are moved up and down at predetermined timings, whereby a film of the flux is provided.

Next, specific flow of procedures of placing the first and second electronic components 200 and 210 on the substrate 101 is specifically described, with reference to the flowchart of FIG. 7.

Upon recognizing that the substrate 101 has been positioned by the substrate holder 309 (SP1), the control unit 313 starts controlling the movements and operations of the placing head 311 as below. First, the placing head 311 picks up the first electronic component 200 from the first component feeding unit 307 by the suction nozzle 311a (SP2), and moves the first electronic component 200 to the transfer unit 310 (SP3). Next, the placing head 311 brings the bumps 204 on the first electronic component 200 into contact with the film of the flux formed on the transfer table of the transfer unit 310, thereby to transfer the flux to the bumps 204 (SP4). In such a manner, the flux 206 is applied to the bumps 204 on the first electronic component 200, as illustrated in FIG. 8(a). In transferring the flux 206 to the bumps 204, it is preferable to control positioning such that the first electronic component 200 lands on the film of the flux at a predetermined position. The thickness of the film of the flux is adjusted appropriately, depending on the size of the bump 204, and the amount of the flux applied to each of the bumps.

Next, the placing head 311 moves the first electronic component 200 to above the first electrodes 102a on the substrate 101 (SP5, FIG. 8(b)), and places the first electronic component 200 on the substrate 101 such that the bumps 204 land on the corresponding first electrodes 102a via the flux 206 (SP6). At that time, as illustrated in FIG. 8(c), part of the flux 206 is transferred from the bumps 204 to the first electrodes 102a, so that the flux 206 fills the gap between the bump 204 and the first electrode 102a. In placing the first electronic component 200 to the first electrodes 102a on the substrate 101, a known image recognition system may be used for accurate positioning based on image data.

Upon completion of the placement of the first electronic component 200 on the substrate 101, the control unit 313 starts controlling the movements and operations of the dispensing head 312 as below. First, the dispensing head 312 moves to above the first electronic component 200, and is positioned (SP7). In positioning the dispensing head 312 also, a known image recognition system may be used for accurate positioning. Then, the dispensing head 312, as shown in FIG. 8(d), dispenses the reinforcing resin 105 through the dispensing nozzles 312a to the reinforcement positions 104 on the substrate 101 corresponding to a peripheral edge portion 201x of the first electronic component 200 (SP8). At that time, if the reinforcing resin 105 does not come in contact with the peripheral edge portion 201x of the first electronic component 200, sufficient reinforcement effect would not be obtained. The peripheral edge portion 201x of the first electronic component 200 is, for example, a peripheral edge portion of a resin substrate 201 included in the BGA electronic component.

Two or more of the reinforcement positions 104 are usually set within an area of the substrate 101 corresponding to the peripheral edge portion 201x of the first electronic component 200. Here, the area of the substrate 101 corresponding to the peripheral edge portion 201x of the first electronic component 200 is a frame-like area set on the substrate, along the outline of the principal surface 201s having the plurality of bumps. The reinforcement positions 104 are set at predetermined points within the frame-like area.

When the dispensing head 312 has the dispensing nozzles 312a with a small diameter, as illustrated in FIG. 8(d), the reinforcing resin 105 is preferably dispensed in dots or lines onto the reinforcement positions 104 through the dispensing nozzles 312a. At that time, adjusting the dispensed amount of the reinforcing resin 105 not to be too much can improve productivity and ease repair work. Moreover, this can prevent defects such as the reinforcing resin 105 being squeezed out.

The step of dispensing the reinforcing resin 105 is preferably performed, with the first electronic component 200 placed on the substrate 101 being pressed toward the substrate 101. For example, as illustrated in FIG. 8(d), the reinforcing resin 105 is dispensed, while the first electronic component 200 is pressed with a pressing terminal 312b provided at the tip end of the dispensing head 312. Such pressing can prevent the first electronic component 200 from being displaced during the dispensing of the reinforcing resin 105. The pressing terminal 312b preferably comprises a member with elasticity in up and down directions, such as a spring, so that the first electronic component 200 will not be subjected to excessive pressure.

The reinforcing resin 105 is preferably dispensed so as to come in contact, not only with the peripheral edge portion 201x of the first electronic component 200, but also with at least one selected from the first electrodes 102a and the bumps 204. As a result, the substrate 101, the first electronic component 200, and the first electrode(s) 102a and/or bump(s) 204 are interconnected to each other, and the reinforcement effect is enhanced.

In order to avoid the reinforcing resin 105 from coming in contact with the first electrodes 102a and the bumps 204, the properties, dispensing amount, dispensing position, etc. of the reinforcing resin 105 should be controlled at an extremely high level. Such a high level of control, however, is more difficult as the first electronic component 200 is smaller in size, and is detrimental to productivity. In the present invention, however, there is little necessity of avoiding the contact of the reinforcing resin 105 with the first electrodes 102a and the bumps 204, since the reinforcing resin 105 is dispensed after the first electronic component 200, with the flux 206 applied to the bumps 204, has been placed on the substrate 101. Rather than dispensing the reinforcing resin 105 so as to avoid the contact, dispensing it so as to come in contact with at least one selected from the first electrodes 102a and the bumps 204 is more advantageous in terms of improved joining strength and improved productivity.

However, if the reinforcing resin 105 enters between the first electronic component 200 and the substrate 101, the amount of the reinforcing resin 105 used would increase, and as in the case of using an underfill material, the time and expense of repair would increase. Moreover, the bumps at the outermost periphery would get covered with the reinforcing resin, which would increase the risk of solder bridging occurring when reflow is performed again. Therefore, it is desirable to bring the reinforcing resin 105 into contact with only the first electrode(s) 102a and/or the bump(s) 204 in the vicinity of the peripheral edge portion 201x of the first electronic component 200, i.e., only the first electrode(s) 102a and/or the bump(s) 204 at the outermost periphery among the regularly arranged first electrodes 102a or bumps 204.

The peripheral edge portion of the typical BGA-type first electronic component is rectangular. In the case where the first electronic component is rectangular, it is preferable to dispense the reinforcing resin onto the reinforcement positions corresponding to at least the four corners, or vicinities of the four corners, of the rectangular peripheral edge portion. Setting the reinforcement positions in such a layout increases the reinforcing effect, even with a small amount of the reinforcing resin. Moreover, this achieves well-balanced reinforcement, and hence, when the first electronic component is subjected to impact, less stress is generated at the solder joints.

Upon completion of the application of the reinforcing resin 105, in response to commands from the control unit 313, the placing head 311 then picks up the second electronic component 210 from the second component feeding unit 308 (SP9), moves the second electronic component 210 to above the second electrodes 102b on the substrate 101 (SP10), and places the second electronic component 210 on the substrate 101, such that the connection terminals land on the paste 103 on the second electrodes 102b (SP11).

The second electronic component 210 may be placed on the substrate 101 before the first electronic component 200 is placed thereon, without being limited to the above order.

The configuration of the electronic component placement machine 303 is not limited to that illustrated in FIG. 4. For example, the second component feeding unit 308 for feeding the second electronic component 210 is incorporated as needed in the electronic component placement machine 303, and is not essential to the electronic component placement machine of the present invention. In other words, in the present invention, the movements and operations of the placing head 311 with respect to the second electronic component 210 may not be performed.

Moreover, as shown in FIG. 9, the control unit 313 may be configured to control, not only the placing head 311 and the dispensing head 312, but also at least one or all of the first component feeding unit 307, the second component feeding unit 308, the substrate holder 309, and the transfer unit 310. For example, the control unit 313 may control the timing when the transfer unit 310 forms the film of the flux, such that it is formed on the transfer table before the first electronic component 200 arrives at the transfer unit 310.

The substrate 101 with the first electronic component 200, and optionally, the second electronic component 210 placed thereon, is carried into a reflow machine (SP12). In the reflow machine, as illustrated in FIG. 10(a), the first electronic component 101 and the reinforcing resin 105 are heated together with the substrate 101, the bumps 204 melts, and thereafter, the reinforcing resin 105 cures and becomes a resin-reinforcing portion 105a. At that time, if there is a displacement between the first electronic component 200 and the substrate 101, the self-alignment effect works to re-align them properly before the reinforcing resin 105 cures. At the completion of the soldering, as illustrated in FIG. 10(b), the shape of the bumps 204 is slightly deformed, and the distance between the first electronic component 200 and the first electrodes 102a is reduced. In the case of using a thermosetting flux, since a cured matter 206a of the flux is formed, the flux washing process can be omitted.

Next, a specific description is given of the dispensing pattern of the reinforcing resin 105.

FIG. 11A is a plan view of the first electronic component 200 when rectangular, on which the reinforcing resin 105 is dispensed at of the four reinforcement positions corresponding to the four corners of the peripheral edge portion 201x of the rectangular first electronic component 200. FIG. 11B is a view of a bottom (the principal surface 201s having the plurality of bumps) of the first electronic component of FIG. 11A. The reinforcing resin 105 is dispensed onto the reinforcement positions so as to come in contact only with at least one of the bumps 204 in the vicinity of the peripheral edge portion 201x of the first electronic component 200 and at least one of the first electrodes 102a (not shown) closest to the peripheral edge portion 201x. Note that there is no particular limitation to the dispensing pattern of the reinforcing resin 105.

FIG. 12 illustrates five exemplary dispensing patterns of the reinforcing resin. In a 4-point dispensing pattern (a), an 8-point dispensing pattern (b), a 12-point dispensing pattern (c), and an L-shaped dispensing pattern (d), the reinforcement positions are set at or near the four corners of the peripheral edge portion of the rectangular first electronic component. In a U-shaped dispensing pattern (e) also, the reinforcement positions are set to include the four corners and vicinities thereof. In the order of the dispensing patterns (a) to (e), the reinforcement effect increases, but the dispensing time becomes longer and the amount of the reinforcing resin used becomes larger. On the other hand, in the order of the dispensing patterns (e) to (a), repair work (reworkability) becomes easier. The dispensing pattern may be selected appropriately, depending on the size and the takt time in the production process of the first electronic component, with the reinforcement effect taken into consideration.

The reinforcing resin may be dispensed to coat the peripheral edge portion almost entirely. In that case, it is desirable to provide an aperture for releasing gas, because gas may be generated from the reinforcing resin or flux during reflowing of the bumps.

Next, a description is given of the flux. The flux may be any material that acts, in soldering, to remove an oxide from a surface of the first electrodes and an oxide from a surface of the bumps, and reduce the surface tension of the solder. These actions (hereinafter, “activating actions”) increase the wettability between the solder and the first electrodes, making possible a highly reliable and good soldering.

The flux composition is not particularly limited, and includes, for example, a base material such as rosin, an activator such as an organic acid or a hydrohalogenic acid salt, a solvent, and a thixotropic agent.

In the present invention, a thermosetting flux is preferably used, assuming that the flux comes in contact with the thermosetting resin serving as the reinforcing resin. In the case of using a thermosetting flux, even when the flux is mixed with the reinforcing resin, the normal thermal curing of the reinforcing resin is unlikely to be inhibited. This is presumably because the migration of active components of the flux to the reinforcing resin is suppressed.

The thermosetting flux can be obtained by adding a thermosetting resin to flux. A preferable example of the thermosetting resin added to flux is an epoxy resin, because of its excellent heat resistance.

Next, a description is given of the reinforcing resin.

The reinforcing resin comprises a thermosetting resin. Examples of the thermosetting resin include epoxy resins, phenol resins, melamine resins, and urethane resins.

The thermosetting resin may contain a curing agent, a cure accelerating agent, and the like. The curing agent is preferably, for example, an acid anhydride, an aliphatic or aromatic amine, or an imidazole or a derivative thereof. The cure accelerating agent is, for example, dicyandiamide.

The reinforcing resin preferably contains a component that acts to remove the oxide from the surfaces of the first electrodes and/or the bumps. For example, an activator to be contained in the flux may be added to the reinforcing resin. This ensures a much more reliable wetting between the molten bumps and the first electrodes, even when the reinforcing resin comes in contact with the first electrodes or the bumps.

The present invention is applicable, not only to the case where one kind of the first electronic component is placed on the substrate, but also to the case where two or more kinds of the first electronic components are placed on the substrate. In the latter case, the electronic component placement machine may be equipped with a nozzle stocker that holds a plurality of suction nozzles to be attached to the placing head, so that the suction nozzle can be replaced according to the kind of the first electronic component. Likewise, the present invention is applicable, not only to the case where one kind of the second electronic component is placed on the substrate, but also to the case where two or more kinds of the second electronic components are placed on the substrate.

Next, the present invention is described by way of Examples, but is not limited to these Examples.

### EXAMPLE 1

First, lands were formed on an FR4 substrate in a predetermined pattern, as first electrodes. A film of flux was formed on a transfer table by using a squeegee, and the film was transferred onto Sn—Ag—Cu solder bumps (melting point: approx. 220° C.) on a flip chip BGA package (1005 chip) used as a first electronic component. Thereafter, the electronic component was placed on the substrate such that the bumps landed on the lands. Next, a reinforcing resin was dispensed in a U-shaped dispensing pattern (FIG. 12(e)) onto two reinforcement positions set so as to include the four corners and vicinities of the peripheral edge portion of the electronic component. At that time, the reinforcing resin was brought into contact with the peripheral edge portion of the electronic component, and with the lands on the substrate and the bumps on the electronic component. Thereafter, the substrate with the electronic component placed thereon was heated at 240° C. to 250° C. in a reflow machine, to solder them to each other.

Next, the soldered electronic component was separated from the substrate, to check whether the bumps sufficiently adhered to the lands. The result found that all of the lands with which the reinforcing resin was brought into contact, had residues of the bumps adhering thereto in sufficient amounts.

### COMPARATIVE EXAMPLE 1

The reinforcing resin was dispensed in the same pattern as that in Example 1, onto the reinforcement positions on the substrate before the electronic component was placed thereon, the reinforcement positions corresponding to the peripheral edge portion of the electronic component. At that time, the reinforcing resin was brought into contact with the edges of the lands on the substrate. Next, the electronic component having the bumps with the film of the flux similar to that of Example 1 was placed on the substrate such that the bumps landed on the lands. At that time, the reinforcing resin came in contact with the peripheral edge portion of the electronic component, as well as with the bumps on the electronic component. Thereafter, the substrate with the electronic component placed thereon was heated in the same reflow machine as in Example 1, to solder them to each other.

Next, the soldered electronic component was separated from the substrate, to check whether the bumps sufficiently adhered to the lands. The result found that some of the lands with which the reinforcing resin was brought into contact, did not have residues of the bumps adhering thereto in sufficient amounts; and that the reinforcing resin have entered between the bumps and the lands.

The foregoing results of Example 1 and Comparative Example 1 show that, according to the present invention, even when the reinforcing resin is brought into contact with the electrode(s) provided on the substrate and/or the bump(s), the reinforcing resin is prevented from entering between the bumps and electrodes. This indicates that the electrodes are sufficiently wetted with the molten bumps during reflow, and thus, electrical connection at the solder joints can be ensured.

### INDUSTRIAL APPLICABILITY

The electronic component mounting method, the electronic component placement machine, and the electronic component mounting system of the present invention can ensure reliable electrical connection and sufficient joining strength between an electronic component and a substrate, in the case where an electronic component having a principal surface provided with a plurality of bumps is joined to a substrate. Therefore, the present invention is particularly useful in the field of surface mounting of small-sized BGA electronic components.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

1. An electronic component mounting method comprising the steps of:
providing a first electronic component having a principal surface provided with a plurality of bumps;
providing a substrate having a plurality of first electrodes corresponding to the plurality of bumps;
applying flux to the plurality of bumps;
placing the first electronic component on the substrate such that the bumps land on the corresponding first electrodes via the flux;
dispensing a thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion; and
heating the substrate with the first electronic component placed thereon, to melt the bumps and cure the thermosetting resin, followed by cooling, thereby to join the first electronic component to the substrate.

2. The electronic component mounting method according to claim 1, wherein the thermosetting resin is dispensed so as to come in contact with at least one selected from the first electrodes and the bumps.

3. The electronic component mounting method according to claim 2, wherein the thermosetting resin is brought into contact with only the first electrode(s) and/or the bump(s) in the vicinity of the peripheral edge portion.

4. The electronic component mounting method according to claim 1, wherein the thermosetting resin contains a component that acts to remove an oxide present on surfaces of the first electrodes and/or the bumps.

5. The electronic component mounting method according to claim 1, wherein the flux is a thermosetting flux.

6. The electronic component mounting method according to claim 1, wherein the principal surface of the first electronic component is rectangular, and the thermosetting resin is dispensed onto the reinforcement positions corresponding to at least four corners, or vicinities of the four corners, of the first electronic component.

7. The electronic component mounting method according to claim 1, wherein the step of dispensing a thermosetting resin is performed while the electronic component placed on the substrate is pressed toward the substrate.

8. The electronic component mounting method according to claim 1, further comprising the steps of:
providing a second electronic component having a connection terminal;
before placing the first electronic component on the substrate, applying a paste containing metal particles by screen printing to a second electrode provided on the substrate, the second electrode corresponding to the connection terminal; and
placing the second electronic component on the substrate such that the connection terminal lands on the second electrode via the paste containing metal particles.

9. An electronic component placement machine adapted to place a first electronic component on a substrate, the first electronic component having a principal surface provided with a plurality of bumps, the substrate having a plurality of first electrodes corresponding to the plurality of bumps, the machine comprising:
a first component feeding unit for feeding the first electronic component;
a substrate holding zone configured to hold and position the substrate;
a transfer unit for providing a film of flux;
a movable placing head for placing the fed first electronic component on the substrate;
a movable dispensing head for dispensing a thermosetting resin; and
a control unit for controlling movements and operations of the placing head and the dispensing head, wherein
in response to commands from the control unit, the placing head transfers the film of flux to the plurality of bumps on the first electronic component, using the transfer unit, and then places the first electronic component on the substrate such that the bumps land on the corresponding first electrodes via the flux; and the dispensing head dispenses the thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion.

10. The electronic component placement machine according to claim 9, wherein the dispensing head comprises a pressing terminal for pressing the electronic component placed on the substrate, toward the substrate, during dispensing of the thermosetting resin.

11. The electronic component placement machine according to claim 9, further comprising a second component feeding unit for feeding a second electronic component having a connection terminal, wherein
in response to commands from the control unit, the placing head places the second electronic component on the substrate, such that the connection terminal lands on a second electrode provided on the substrate, the second electrode corresponding to the connection terminal.

12. An electronic component mounting method in which a first electronic component and a second electronic component are mounted on a substrate, the first electronic component having a principal surface provided with a plurality of bumps, the second electronic component having a connection terminal, the substrate having a plurality of first electrodes corresponding to the plurality of bumps and a second electrode corresponding to the connection terminal, the method comprising the steps of:
providing the substrate;
applying a paste containing metal particles by screen printing to the second electrode on the substrate;
providing the first electronic component;
providing the second electronic component;
applying flux to the plurality of bumps;
placing the first electronic component on the substrate such that the bumps land on the corresponding first electrodes via the flux;
dispensing a thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion;
placing the second electronic component on the substrate such that the connection terminal lands on the second electrode via the paste containing metal particles; and
heating the substrate with the first electronic component and the second electronic component placed thereon, to melt the bumps and the metal particles, and cure the thermosetting resin, followed by cooling, thereby to join the first electronic component and the second electronic component to the substrate.

13. An electronic component mounting system adapted to mount a first electronic component and a second electronic component on a substrate, the first electronic component having a principal surface provided with a plurality of bumps, the second electronic component having a connection terminal, the substrate having a plurality of first electrodes corresponding to the plurality of bumps and a second electrode corresponding to the connection terminal,
the system comprising:
a substrate feeding machine for feeding the substrate;
a screen printing machine for applying a paste containing metal particles by screen printing to the second electrode on the substrate carried from the substrate feeding machine;
an electronic component placement machine for placing the first electronic component and the second electronic component on the first electrodes and the second electrode, respectively, on the substrate carried from the screen printing machine, the second electrode having the paste containing metal particles applied thereto; and
a reflow machine for heating the substrate carried from the electronic component placement machine, to melt the bumps and the metal particles, and cure the thermosetting resin, wherein
the electronic component placement machine comprises:
a first component feeding unit for feeding the first electronic component;
a second component feeding unit for feeding the second electronic component;
a substrate holding zone configured to hold and position the substrate;
a transfer unit for providing a film of flux;
a movable placing head for placing the fed first electronic component and the fed second electronic component on the substrate;
a movable dispensing head for dispensing the thermosetting resin; and
a control unit for controlling movements and operations of the placing head and the dispensing head, wherein
in response to commands from the control unit, the placing head transfers the film of flux to the plurality of bumps on the first electronic component, using the transfer unit, and then places the first electronic component on the substrate such that the bumps land on the corresponding first electrodes via the flux and places the second electronic component on the substrate such that the connection terminal lands on the second electrode via the paste containing metal particles; and the dispensing head dispenses the thermosetting resin onto at least one reinforcement position on the substrate with the first electronic component placed thereon, the at least one reinforcement position corresponding to a peripheral edge portion of the first electronic component, the thermosetting resin dispensed so as to come in contact with the peripheral edge portion.
